(19) United States
(12) Patent Application Publication
(10) Pub. No.: US 2020/0098430 A1
(43) Pub. Date: Mar. 26, 2020

(54) CAM MACRO CIRCUIT AND SEMICONDUCTOR INTEGRATED CIRCUIT

(71) Applicants: Kabushiki Kaisha Toshiba, Tokyo (JP); Toshiba Electronic Devices & Storage Corporation, Tokyo (JP)

(72) Inventor: Kenich Anzou, Kawaski Kanagawa (JP)

(21) Appl. No.: 16/289,809

(22) Filed: Mar. 1, 2019

(30) Foreign Application Priority Data
Sep. 20, 2018 (JP) 2018-175826

(51) Int. Cl. G11C 15/04; G11C 29/12

(52) U.S. Cl. CPC G11C 15/04; G11C 29/12

(57) ABSTRACT

According to one embodiment, there is provided a content addressable memory (CAM) macro The CAM macro circuit includes a first circuit that does not precharge a match line corresponding to a word having a valid bit being off and precharges a match line corresponding to a word having a valid bit being on in a CAM, and a second circuit that causes a sense amplifier of a match line corresponding to a word having a valid bit being off to operate in accordance with a specific signal.

### CROSS-REFERENCE TO RELATED APPLICATIONS

This application is based upon and claims the benefit of priority from Japanese Patent Application No. 2018-175826, filed Sep. 20, 2018, the entire contents of which are incorporated herein by reference.

### FIELD

Embodiments described herein relate generally to a CAM macro circuit and a semiconductor integrated circuit.

### BACKGROUND

Generally, a content addressable memory (CAM) macro circuit, such as ternary content addressable memory (TCAM) or binary content addressable memory (BCAM), is configured so that when comparing a plurality of words with input data, a match line corresponding to a word which is not an object to be compared is not precharged and a sense amplifier of the match line is not operated, for saving power.

For example, in a CAM circuit before factory shipment, when a failure occurs in or around a precharge circuit of any match line, even if a corresponding word is not an object to be compared, the match line may be precharged. At that time, a sense amplifier of the match line is not operated, and the phenomenon described above does not appear on the output side of the sense amplifier, resulting in the detection of no failure.

### BRIEF DESCRIPTION OF THE DRAWINGS

FIG. 1 is a diagram illustrating an example of a schematic configuration of a ternary content addressable memory (TCAM) macro circuit implemented in a semiconductor integrated circuit according to an embodiment;

FIG. 2 is a diagram illustrating a phenomenon appearing on a match line ML when all results of comparison of a word being an object to be compared indicate a match;

FIG. 3 is a diagram illustrating a phenomenon appearing on a match line ML when a result of a comparison of a word being an object to be compared indicates a mismatch;

FIG. 4 is a diagram illustrating an example of a circuit configuration enabling; testing a precharge circuit connected to a match line ML corresponding to one word;

FIG. 5 is a diagram illustrating an example of a configuration of a built-in self-test (BIST) circuit and a TCAM macro circuit; and

FIG. 6 is a flowchart illustrating an example of test operation by the BIST circuit.

### DETAILED DESCRIPTION

Hereinafter, embodiments will be described with reference to the drawings.

In general, according to one embodiment, there is provided a content addressable memory (CAM) macro circuit. The CAM macro circuit includes a first circuit that does not precharge a match line corresponding to a word having a valid bit being off and precharges a match line corresponding to a word having a valid bit being on in a CAM, and a second circuit that causes a sense amplifier of a match line corresponding to a word having a valid bit being off to operate in accordance with a specific signal.

(Basic Configuration)

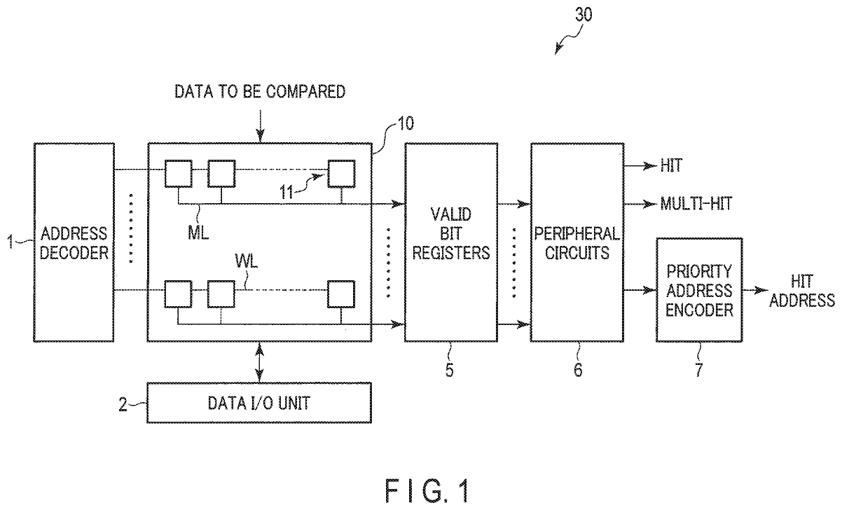

FIG. 1 is a diagram illustrating an example of a schematic configuration of a ternary content addressable memory (TCAM) macro circuit implemented in a semiconductor integrated circuit according to an embodiment.

In the present embodiment, a TCAM adopted as an example of a CAM is exemplified, but a binary content addressable memory (SCAM) may be adopted instead of the TCAM. Furthermore, there are two types of TCAMs used in the present embodiment, the TCAMs have different structures, one of which is called a symmetric TCAM and the other of which is called an asymmetric TCAM, but either one may be adopted. In either case, it is possible to achieve functions, processing, operations, and the like described later.

A TCAM macro circuit 30 illustrated in FIG. 1 includes a TCAM cell array 10. In addition, the TCAM macro circuit 30 includes an address decoder 1, a data I/O unit 2, valid bit registers 5, peripheral circuits 6, a priority address encoder 7, and the like around the TCAM cell array 10.

The TCAM cell array 10 has a plurality of TCAM cells 11. Each of these cells 11 is achieved based on a bit cell of a static random access memory (SRAM), has a circuit for data comparison, is connected to a word line WL for each word, and is also connected to a match line ML. The match lines ML extend to the peripheral circuits 6 via the valid bit registers 5.

The address decoder 1 is configured to decode an address to select a word line WL corresponding to a word being an object to be read/written.

The data I/O unit 2 performs input/output processing of data to be read/written for each cell 11.

The valid bit registers 5 each hold a value of a valid hit indicating whether a word is an object to be compared, for each word (for each word line WL or each match line ML), and supplies the value of the valid bit to each of the peripheral circuits 6. For example, when the word is the object to be compared, the value of the valid bit is set to “1” (on state), and when the word is not the object to be compared, the value of the valid bit is set to “0” (off state).

The peripheral circuits 6 each compare a word being an object to be compared and data to be compared (comparand) according to the value of the valid bit for each word, and outputs a result of the comparison through a corresponding match line ML. In this comparison operation, comparison processing is basically performed on all the cells 11. However, comparison processing is not performed on a word having a valid bit of “0”. The result of the comparison is not limited to a single match. (hit), and multiple hits may he obtained from results of comparison of a plurality of preceding and following words. The result of the comparison of each word may be stored in a predetermined storage area in the form of a match flag. When the results of the comparison in a match, the value of the match flag is set to “1”, and when the results of the comparison in a mismatch, the value of the match flag is set to “0”.

When there is a plurality of hits, the priority address encoder 7 outputs an address having the highest priority (for example, a maximum address or a minimum address) as a match address. In the case of a single hit, this address is output as the match address.

The information about the match flag and the match address described above may be output to the outside of the TEAM macro circuit 30.

(Match and Mismatch)

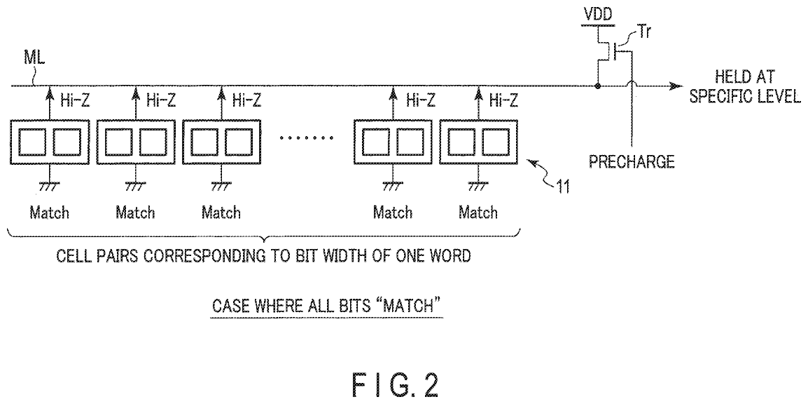

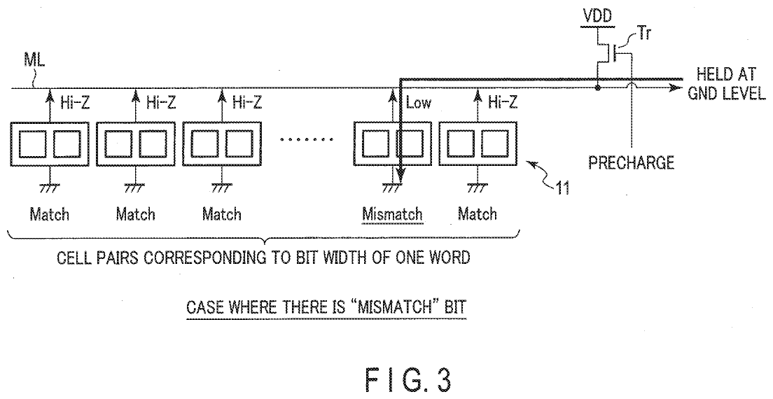

Next, a description is given of a difference between a phenomenon appearing on the match line ML when all of the results of comparison of the words being an object to be compared indicate a match and a phenomenon appearing on the match line ML when the results of the comparisons contain a mismatch, with reference to FIGS. 2 and 3.

As illustrated in FIG. 2, cell pairs corresponding to a bit width of one word is connected to a match line ML corresponding to one word. The individual cells 11 are connected between the match line ML and the ground.

Before the comparison operation, the match line ML is precharged to a specific voltage level (for example, a midpoint potential between 0 and VDD in terms of power saving) by a precharge circuit including a transistor Tr.

Then, during the comparison operation, when all bit data indicates matching with data to be compared, output from all cells 11 to the match line ML is, for example, High-Z, and the specific voltage level in the match line ML remains held.

In contrast, as illustrated in FIG. 3, in the comparison operation, when any bit data indicates a mismatch, a charge on the match line ML passes through a transistor constituting a corresponding cell 11 to the ground, and the voltage level of the match line ML drops to the ground level.

(Configuration Enabling Testing Precharge Circuit)

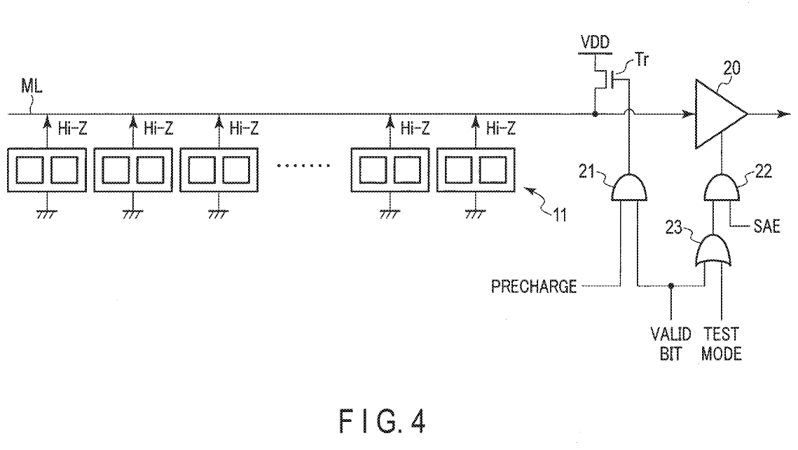

FIG. 4 is a diagram illustrating an example of a circuit configuration enabling testing a precharge circuit connected to a match line ML corresponding to one word.

As illustrated in FIG. 4, on the output side of the match line ML, there is provided a sense amplifier 20 which amplifies the voltage level of the match line ML and outputs the amplified voltage level. Thus, for example, when the match line ML is at a midpoint potential, it is possible to output a voltage having a level satisfying a logical value 1. In addition, on the output side of the match line ML, the transistor Tr described above is provided between the power supply VDD and the match line ML.

In addition, an AND circuit 21, an AND circuit 22, and an OR circuit 23 which constitute a logic circuit are provided in the periphery. The precharge circuit includes at least the AND circuit 21 and the transistor Tr.

The AND circuit 21 receives an input of a value (“1” or “0”) of the valid bit transmitted from a valid hit register of the valid bit registers 5 corresponding to the word and an input of a value (“1” or “0”) of a precharge signal indicating whether to perform precharge, and gives the transistor Tr a value (“1” or “0”) of logical conjunction of both of the values of the valid bit and precharge signal.

The AND circuit 22 receives an input of a value (“1” or “0”) of a sense amplifier enable (SAE) signal indicating whether to enable the sense amplifier 20 and an input of a value (“1” or “0”) of an output signal from the OR circuit 23, and gives a value (“1” or “0”) of logical conjunction of both values of the sense amplifier enable (SAE) signal and the output signal to the sense amplifier 20.

The OR circuit 23 receives an input of a value (“1” or “0”) of the valid bit and an input of a value (“1” or “0”) of a test mode signal indicating whether to perform a test, and supplies a value (“1” or “0”) of logical disjunction of both values of the valid bit and the test mode signal to one input portion of the AND circuit 22.

(Normal Operation Mode)

In a normal operation mode in which the test is not performed, the test mode signal has a value of “0”.

In this state, when performing the comparison processing, the valid bit has a value of “1”. When the precharge signal has a value of “1” to precharge a match line ML, the value of an output signal from the AND circuit 21 is “1” and given to the gate of the transistor Tr. Thus, the transistor Tr is conducted, and the match line. ML is precharged. In addition, the output signal from the OR circuit 23 is “1”, the value of an output signal from the AND circuit 22 is “1” and given to the sense amplifier 20, and the sense amplifier 20 is brought into an operation state.

Accordingly, the result of the comparison processing is reflected in the voltage level of the match line ML and is obtained as a logical value (“1” or “0”) through the sense amplifier 20 in the operation state. When all the results of comparison of the word being an object to be compared indicate the match, the logical value of an output from the sense amplifier 20 is “1”, and when the results of the comparison contain a mismatch, the logical value of an output from the sense amplifier 20 is “0”

On the other hand, when comparison processing is not performed, the value of the valid bit is “0”. Since the match line ML is not precharged, the value of the precharge signal is “0” and the value of the output signal from the AND circuit 21 is “0”. The transistor Tr is in a non-conductive state, and the match line ML is not precharged. Furthermore, the output signal from the OR circuit 23 is “0”, the value of the output signal from the AND circuit 22 is “0”, and the sense amplifier 20 does not operate. The reason why the sense amplifier 20 is not operated at this time is to save power.

(Failure of Precharge Circuit)

When the match line ML is precharged while the comparison processing is not performed as described above, it is considered that a failure has occurred in or around the precharge circuit. At this time, since the sense amplifier 20 does not operate, the phenomenon that the match line ML is precharged due to a failure cannot be detected from an output from the sense amplifier 20.

Positions where the failure occurs include, for example, the transistor Tr, the AND circuit 21, a circuit (not illustrated) on the supply side of the valid bit, and a circuit (not illustrated) on the supply side of the precharge signal. Examples of the type of failure include a failure in which the transistor Tr will not be turned off, a failure in which the output value from the AND circuit 21 will not become “0”, a failure in which the output value from a circuit on the supply side of the valid bit will not become “0”, and a failure in which the output value from a circuit on the supply side of the precharge signal will not become “0”.

(Test Mode)

In a test mode in which the test is performed, the test mode signal has a value of “1”.

When the precharge circuit corresponding to a certain word is tested, such values that all results of comparison with the data to be compared indicate the match in the comparison operation are written to the respective cells of the word in advance.

The comparison processing is performed in a state in which the value of the test mode signal is set to “1”, the value of the SAE signal is set to “1”, the value of the valid bit is set to “0”, and the value of the precharge signal is set to “0”.

In this state, the output value from the OR circuit 23 is “1”, the value of the SAE signal is “1”, and the output value from the AND circuit 22 is “1”, since the value of the test mode signal is “1”, and it is indicated that the sense amplifier 20 is in the operation state.

Furthermore, in this state, when there is no failure in or around the precharge circuit, the match line ML is not precharged. Thus, even when all results of comparison of the word being an object to be compared indicate the match, the logical value obtained through the sense amplifier 20 is not “1” but “0”. When this logical value “0” is obtained., it can be considered that there is no failure.

On the other hand, when a failure occurs in or around the precharge circuit, the match line ML is precharged, and when all results of comparison of the words being an object to be compared indicate the match, the logical value “1” is obtained through the sense amplifier 20. When this logical value “1” is obtained, it can be considered that a failure has occurred.

As described above, the OR circuit 23 provided in the TCAM macro circuit 30 enables causing a sense amplifier of a match line ML corresponding to a word, the valid bit of which has a value of “0”, to operate in the test mode, and It is possible to detect a failure occurring in or around the precharge circuit, from an output from the sense amplifier.

(Configuration Including BIST Circuit and TCAM Macro Circuit)

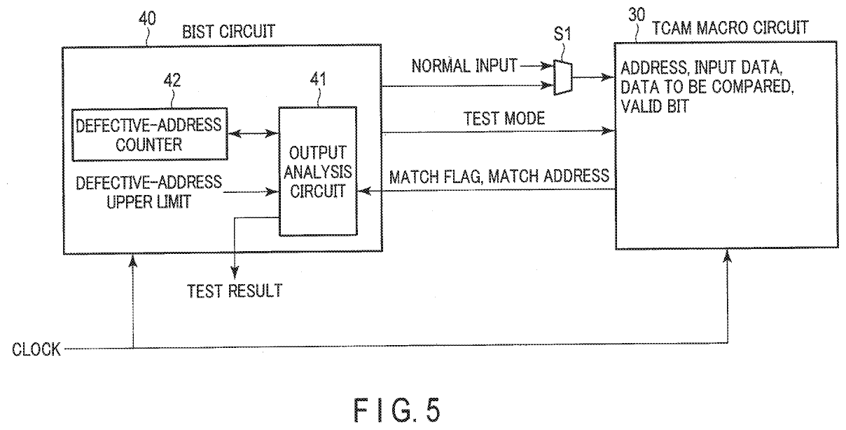

FIG. 5 is a diagram illustrating an example of a configuration of a built-in self-test (BIST) circuit and the TCAM macro circuit which are implemented in the semiconductor integrated circuit according to the present embodiment

As illustrated in FIG. 5, in addition to the TCAM macro circuit 30, the BIST circuit. 40 for testing the TCAM macro circuit 30 is implemented in the semiconductor integrated circuit according to the present embodiment. The TCAM macro circuit 30 and the BIST circuit 40 to be tested operate in synchronization with a clock.

The BIST circuit 40 is provided with an output analysis circuit 41 and a defective-address counter 42. However, the defective-address counter 42 is not necessarily required and may not be provided.

In the normal operation mode, the TCAM macro circuit 30 receives information, such as address, input data, data to be compared, and valid bit, necessary for normal operation, through a selector S1.

When performing the test, the BIST circuit 40 transmits a specific signal (that is, a test mode signal having a logical value of “1”) to the CAM macro circuit 30. The specific signal causes a sense amplifier 20 of a match line ML to operate, where the match line ML is connected to a precharge circuit being an object to be tested of the precharge circuits provided for the respective match lines ML in the TCAM macro circuit 30. In addition, for the test, the BIST circuit 40 appropriately transmits information, such as address, input data, data to be compared, and valid bit to the CAM macro circuit 30.

In the test mode, the TCAM macro circuit 30 receives the test mode signal for setting the logical value to “1”, from the side of the BIST circuit 40. Furthermore, in the test mode, a source from which information is input to the selector S1 is switched to the BIST circuit 40 so that the TCAM macro circuit 30 can receive information as described above, from the BIST circuit 40 through the selector S1. In the test mode, the TCAM macro circuit 30 performs comparison processing for each word and transmits the match flag and the match address obtained from an output from the sense amplifier 20, to the BIST circuit 40. The match flag indicates a result of comparison processing performed for each word (presence/absence of a match). The match address indicates an address corresponding to a word indicating a match.

The output analysis circuit 41 receives information about the match flag and the match address transmitted from the CAM macro circuit 30, determines the presence/absence of a failure based on the information about each object to be tested obtained from the reception, and outputs a result. In that case, the output analysis circuit 41 may have a function of obtaining the number of failures (the number of defects for each address) or the percentage of failures (the percentage of defects for each address) from the information about each object to be tested obtained from the reception by using the defective-address counter 42, and determining that the CAM macro circuit 30 is defective when the number or the percentage of failures exceeds a threshold value (defective-address upper limit). However, this function is not an essential element. When using this function, for example, the output analysis circuit 41 may increment a count value of the defective-address counter 42 every time the match flag indicating a value of “1” appears, and determine that the CAM macro circuit 30 is defective when the count value exceeds the defective-address upper limit.

(Test Operation)

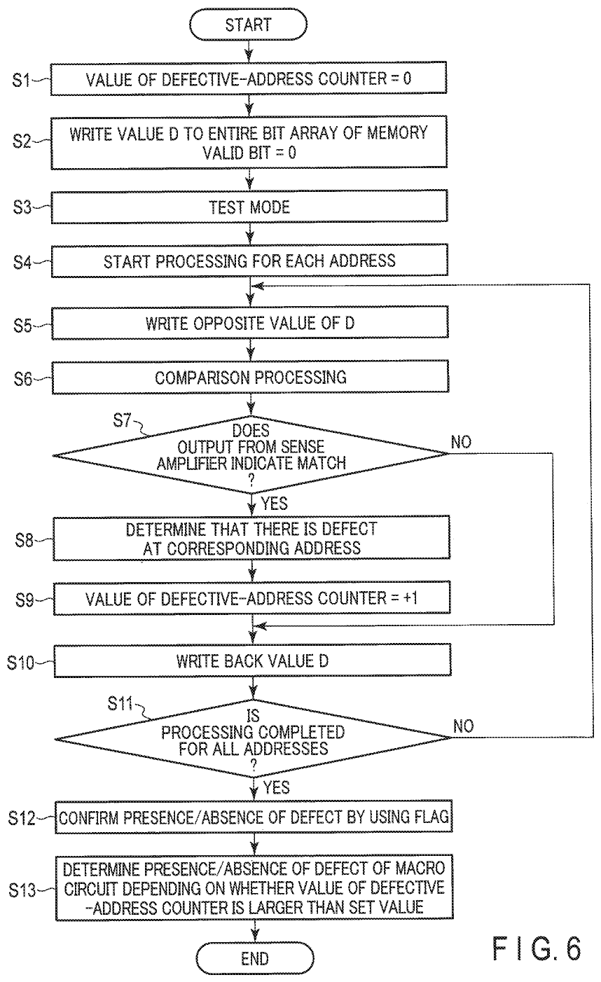

Next, an example of test operation by the BIST circuit 40 will be described with reference to a flowchart of FIG. 6. In this example, the defective-address counter 42 is used.

The BIST circuit 40 initializes the value of the defective-address counter to 0 (step S1), and writes a value “D” (for example, “0”) to the entire bit array of the TCAM (step At that time, the value of the valid bit of each address is set to “0”.

Then, the BIST circuit 40 transmits the test mode signal having a value of “1” to the CAM macro circuit 30 to set the CAM macro circuit 30 to the test mode (step S3) and starts processing for each address (processing for each word) (step S4).

The BIST circuit 40 writes an “opposite value of D” (for example, “1”) into each cell of a word being an object to he tested (address being an object to be tested) (step S5) for comparison with data to be compared indicating the same “opposite value of D” (step 86).

Next, the output analysis circuit 41 of the BIST circuit 40 determines whether an output from the sense amplifier 20 indicates a match at this address (step S7). When the match is not indicated (NO in step S7), it is considered that there is no defect at the address, and the process proceeds to step S10. On the other hand, when the match is indicated (YES in step S7), it is determined that there is a defect at the address (step S8), and in that case, the output analysis circuit 41 increments a count value of the defective-address counter 42 (step S9). Then, the output analysis circuit 41 writes back the value D (for example, “0”) to each cell of the address (step S10).

Steps S5 to S10 are repeated until processing is completed for all addresses (step S11).

Upon completion of processing for all the addresses, the output analysis circuit 41 confirms whether a defect is detected by using the match flag and outputs the result (step S12).

When the count value of the defective-address counter 42 is larger than a predetermined set value, the output analysis circuit 41 determines that the TCAM macro circuit 30 is defective and outputs the result (step S13).

In this operation example, the operation using the defective-address counter 42 is described, but the present invention is not limited to this, and the test may be performed without using the defective-address counter 42. In that configuration, the processing of steps S1, S9, and S13 described above are omitted.

According to the present embodiment, when there is a failure in or around the precharge circuit and there is a phenomenon that a match line corresponding to a word which is not an object to be compared is precharged, a failure is readily detected based on an output from the sense amplifier in the test.

Furthermore, components added to the TCAM macro circuit are only an OR circuit added for each word and wiring for connecting the OR circuits, and minor improvement is enough.

As described in detail above, according to the embodiments, it is possible to readily detect a failure occurring in or around a precharge circuit in a CAM circuit.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made. The accompanying claims and their equivalents are intended to cover such forms or modifications as would fall within the scope of the inventions.

1. A content addressable memory (CAM) macro circuit comprising:
a first circuit that does not precharge a match line corresponding to a word having a valid bit being off and precharges a match line corresponding to a word having a valid bit being on in a CAM; and
a second circuit that causes a sense amplifier of a match line corresponding to a word having a valid bit being off to operate in accordance with a specific signal.

2. The CAM macro circuit according to claim 1, wherein.
the specific signal causes a sense amplifier of a match line to operate, where the match line is connected to a precharge circuit being an object to be tested of precharge circuits provided for respective match lines.

3. The CAM macro circuit according to claim 1, wherein
the second circuit includes a logic circuit that receives an input of a value of the valid bit and an input of a value of the specific signal, and outputs a value operating a corresponding sense amplifier.

4. The CAM macro circuit according to claim 3, wherein
the logic circuit includes an OR circuit that outputs a value of logical disjunction of two input values.

5. The CAM macro circuit according to claim 1, wherein
a match line connected to a precharge circuit being an object to be tested is discharged before comparison operation.

6. The CAM macro circuit according to claim 1, wherein
when, while the valid bit is off, a match line is precharged due to a failure of a precharge circuit being an object to be tested,
a value different from an expected value is output from a sense amplifier of the match line.

7. A semiconductor integrated circuit comprising:
the CAM macro circuit according to claim 1; and
a built-in self-test (BIST) circuit that tests the CAM macro circuit.

8. The semiconductor integrated circuit according to claim 7, wherein
the BIST transmits the specific signal to the CAM macro circuit to cause a sense amplifier of a match line to operate, where the match line is connected to a precharge circuit being an object to be tested of precharge circuits provided for respective match lines.

9. The semiconductor integrated circuit according to claim 7, wherein
The BIST circuit receives, from the CAM macro circuit, information corresponding to a value output from a sense amplifier of a match line connected to a precharge circuit being an object to be tested, and determines the presence/absence of a failure based on information about each object to be tested obtained from the reception.

10. The semiconductor integrated circuit according to claim 7, wherein
the BIST circuit receives, from the CAM macro circuit, information corresponding to a value output from a sense amplifier of a match line connected to a precharge circuit being an object to be tested, obtains the number of failures or a percentage of failures based on information about each object to be tested obtained from the reception, and determines that the CAM macro circuit is defective when the number or the percentage of failures exceeds a threshold value.
